(19) United States
(12) Patent Application Publication
(10) Pub. No.: US 2014/0318614 A1
(43) Pub. Date: Oct. 30, 2014

(54) BACK-CONTACT SOLAR CELL AND METHOD FOR PRODUCING SUCH A BACK-CONTACT SOLAR CELL

(71) Applicants: Hilmar Von Campe, Bad Homburg (DE); Christine Meyer, Karlsruhe (DE); Stephan Huber, Rechtmehring (DE)

(72) Inventors: Hilmar Von Campe, Bad Homburg (DE); Christine Meyer, Karlsruhe (DE); Stephan Huber, Rechtmehring (DE)

(73) Assignee: FRAUNHOFER-GESELLSCHAFT ZUR FOERDERUNG DER ANGEWANDTEN FORSCHUNG E.V, Munich (DE)

(21) Appl. No.: 14/118,107

(22) PCT Filed: May 15, 2012
(86) PCT No.: PCT/EP2012/059002

§ 371 Date: Feb. 6, 2014

(30) Foreign Application Priority Data
May 17, 2011 (DE) 10 2011050 434.6
Jun. 1, 2011 (DE) 10 2011 050 803.1
Jul. 1, 2011 (DE) 10 2011051 511.9

(51) Int. Cl. H01L 31/0224; H01L 31/02

(52) U.S. Cl. CPC H01L 31/02245; H01L 31/02008
USPC 136/256; 438/98

(57) ABSTRACT

A method for producing a solar cell that has a semiconductor substrate of a first conductivity type. The method includes producing a plurality of passage openings, creating a layer of a conductivity type opposite the first conductivity type along a front side, producing a front-side contact in the form of a metallization and a back-side contact. Electrically conductive front-side contact areas bound the passage openings on the front side and are formed when the front-side contact is formed. The passage openings are provided with an electrically insulating first layer on the inside, and an electrically conductive material is subsequently introduced, starting from a back side, through the passage openings up to the front-side contact areas while back-side contact areas are simultaneously formed.

The invention relates to a method for producing a solar cell having a semiconductor substrate of a first conductivity type, in particular a p-silicon-based crystalline semiconductor substrate, which has a front side and a back side, comprising the method steps of:
producing a plurality of passage openings extending from the front side to the back side;
creating a layer of a conductivity type that is opposite to the first conductivity type along the front side;
producing a front-side contact in the form of a metallizing with electrically conducting front-side contact regions adjacent to the passage openings on the front side, as well as a back-side contact, wherein the front-side contact is connected in an electrically conducting manner with the back-side contact regions that are electrically isolated or insulated with respect to the back side adjacent to the passage openings on the back side, by introducing an electrically conducting material into the passage openings, which have on the inside either an electrically insulating first layer or a layer of the conductivity type opposite to the first conductivity type; and
connecting the back-side contact regions to one another.

The indicated method steps need not be performed in the above-given sequence.

The invention also refers to a back-side contact solar cell having a semiconductor substrate of a first conductivity type, in particular a p-silicon-based crystalline semiconductor substrate, which has a front side and a back side, with
front-side layer of a conductivity type opposite to the first conductivity type;
a plurality of passage openings extending from the front side to the back side;
front-side contact formed by a front-side metallizing as well as back-side contact;
wherein the front-side contact is connected in an electrically conducting manner by the passage openings with the back-side contact regions surrounding the passage openings on the back side, and the back-side contact regions are connected to one another in an electrically conducting manner and are electrically isolated or insulated with respect to the back side, wherein at least several of the passage openings are arranged in a row, the passage openings are delimited on the front side by an electrically conducting contact region, and the passage openings have on the inside either an electrically insulating first layer or a layer of the conductivity type opposite to the first conductivity type.

In order to provide suitable voltages or powers, it is known to connect these solar cells into larger units. For the production of corresponding modules, the cells are connected to one another in parallel or in series, and embedded in a suitable transparent encapsulating material, such as ethylene vinyl acetate (EVA). On the front side, corresponding modules are usually covered by a glass panel, and on the back side by a weather-resistant composite plastic film such as polyvinyl fluoride (TEDLAR) and polyester. The module itself can be taken up by an aluminum frame.

Typical solar cell modules based on silicon wafers have contacts on the front and back sides. Since among other things, the efficiency of a solar cell depends on the uncovered front surface for the incident solar radiation, but front-side contacts limit the effective surface, back-side contact solar cells have been developed that are known as WRAP-THROUGH solar cells. Here, metal wrap-through (MWT) cells are distinguished from emitter wrap-through (EWT) cells. In the case of MWT cells, metallizing is introduced on the front side, which is composed of running fingers that radiate out to a discontinuity as a current sink, and is guided through the passage opening to the back side. These regions must be electrically separated from the back-side contact, in order to avoid short circuits.

The production of corresponding back-side contact solar cells is complex and requires a high process reliability.

Back-side contact solar cells can be derived, e.g., from US-A-2010/70243040, WO-A-2010/081505, DE-A-10 2009 059 156 or DE-A-10 2006 052 018.

MWT solar cells can be taken from JP-A-2008034609 and US-A-2010/0275987. In order to produce the electrically conducting connection between the front contact to the back side, a paste material that contains, in particular, a glass frit as well as partially a metal powder composed of silver is introduced into the passage opening. After introducing or applying the paste, a temperature treatment is then conducted between 500° C. and 850° C.

In order to connect a contact element to a solar cell, DE-A-36 14 849 provides a resistance welding process, wherein an ultrasonic welding pulse is first applied to the contact element.

The object of the present invention is based on enhancing a method for producing a back-side contact solar cell and such a back-side contact solar cell that can be produced in a more cost-favorable manner in comparison to the prior art and also will be stable for a long time. Further, a reliable contacting shall be made possible by the passage openings. Also, a problem-free design of the contacts electrically insulated from one another on the back side will be made possible.

According to the method, the object is essentially achieved in that a soldering material is introduced, supported by ultrasound, as the electrically conducting material, proceeding from the back side through the passage openings to the front-side contact regions, with simultaneous formation of the back-side contact regions.

According to the invention, a soldering material is employed in order to produce the electrically conducting connection between the front and back sides of the MWT solar cell. In this case, the soldering material is introduced, supported by ultrasound, proceeding from the back side into the passage openings—also called vias, and in fact, in particular, simultaneously to when a strip designated as an electrically conducting second contact is applied onto an electrically insulating layer on the back side. The soldering material is passed through the passage openings up to the front-side contact region. The soldering strip can thus be applied in a way such as is described in DE-B-10 2010 016 814, the disclosure of which is expressly referenced.

Thus, the solder wire is introduced into a gap running between a heating means and a tool such as a sonotrode applying the ultrasonic vibrations, and is melted. The molten solder then flows through the gap onto the back side of the solar cell. A reliable soldering on of the solder results due to this measure.

It is provided, in particular, that in the case of the front-side metallizing of the semiconductor substrate, the fingers leading to the current sink, e.g., radiating out, pass over into an annular contact region adjacent to the passage opening on the front side. The metallizing, including the annular contact region preferably made of silver or containing silver can be created by a printing process, such as a screen printing process or by a masking technique. Instead of an annular contact region, another type can be created that covers, i.e., closes, the passage opening on the front side.

After forming the flat-surface back-side contact, preferably in the form of a layer composed of aluminum or containing aluminum, an insulating layer made of, e.g., an inorganic material (alternatively, an organic insulating layer is also possible) can be applied onto this, this insulating layer composed of a strip that extends along passage openings arranged in a row, whereby the inorganic insulating layer material can pass through the passage openings in order to avoid a separate method step for the formation of the electrically insulating first layer.

Glass ceramics (lower melting point) or screen-printed TiO₂ pastes are considered as inorganic insulating layer material. There exists also the possibility of locally spraying on a phosphorus-glass layer for the formation of the insulating layer. In particular, dielectrics precipitated from the gas phase or polymeric coatings are also suitable.

Independently from this, it is particularly provided that the insulating layer is formed by a local spraying method, by screen printing, or by oxidation of the porous silicon (substrate material) at approximately 400° C.-1100° C., preferably 500° C.-800° C.

The electrically conducting material is subsequently introduced in strip form onto the insulating layer, whereby, under the effect of ultrasonic vibrations, it penetrates into the passage openings up to the front-side metallizing or up to the annular contact regions. In this way, an electrically conducting connection is assured between the front-side metallizing and the back side of the solar cell.

The corresponding strip-shaped contacts that are to be designated as first contacts are then connected to one another in an electrically conducting manner by an interconnecting structure in an edge region of the solar cell. Solar cells are connected via the interconnecting structure. The interconnecting structure thus in one region has a “comb” geometry, the lengthwise tines or legs of which are connected in an electrically conducting manner with the first contacts.

An electrically conducting material is likewise introduced in strip form as a second strip-shaped contact between the strip-shaped insulating layer segments on the back-side contact, whereby the individual second contacts are also connected to one another, and in fact on the side of the solar cell lying opposite with respect to the connection for the first contacts. Thus, a comb structure likewise results.

In a corresponding structure, a problem-free connection of solar cells arranged in rows to form a module is possible, by connecting the connections of first contacts of a first solar cell to second contacts of a subsequent solar cell.

The first and second strip-shaped contacts can also be called busbars, whereby the second contacts can be introduced in particular by screen printing.

The first strip-shaped contacts can be produced by applying a molten solder wire, whereby ultrasonic vibrations can be introduced to the extent necessary by means of a sonotrode during the application. In this case, for simplifying the production technology, a number of sonotrodes can be used corresponding to the first strip-shaped contacts running substantially parallel to one another, so that the corresponding first strip-shaped contacts are applied simultaneously, the soldering material penetrating simultaneously into the passage openings.

The electrically conducting material both for the first as well as for the second strip-shaped contacts involves a soldering material such as tin, or a soldering material based on tin/zinc or tin/silver. Other suitable materials such as tin-lead or any other soldering paste materials also can be considered.

The invention is thus characterized in that at least several of the passage openings are arranged in at least one row running along a line, such as a straight line, whereby after producing the front-side contact with the front-side contact regions, an electrically insulating second layer is introduced on the back side of the solar cell. This can extend into the passage opening for the formation of the electrically insulating first layer. Of course, this is not absolutely necessary, if the passage openings have on the inside a layer of the conductivity type that is opposite to the first conductivity type.

It is provided that after applying the second electrically insulating layer onto this layer along the line, the electrically conducting material extending through the passage openings is applied in strip form for the formation of first strip-shaped contacts.

It is provided, in particular, that at least several of the passage openings are disposed in at least two, preferably three rows running parallel to one another, whereby a strip-shaped segment of the second electrically insulating layer runs along each row and, parallel to the segments, at least one strip-shaped second contact connected to the back-side contact is formed. In this case, the first and second strip-shaped contacts are connected in an electrically conducting manner to one another in opposite-lying edge regions of the solar cell.

For the formation of the first strip-shaped contacts, a sonotrode that can apply ultrasonic vibrations should be guided along each row of the passage openings, and by means of this sonotrode, ultrasonic vibrations are transmitted onto the respective strip-shaped, applied electrically conducting material for the formation of the first strip-shaped contacts and introduction of the electrically conducting material into the passage opening. In this case, it is particularly provided that ultrasonic vibrations act simultaneously on each strip-shaped contact.

A back-side contact solar cell of the type named initially is characterized in that an electrically insulating second layer running along the back side extends in strip form along the passage openings arranged in the row, and in that soldering material as an electrically conducting material applied with ultrasound support extends along the electrically insulating second layer through the passage openings to the front-side contact regions, whereby the electrically conducting material extending along the electrically insulating second layer forms an electrically conducting first contact, whereby then, if the passage openings have on the inside the electrically insulating first layers, the first layers are segments of the electrically insulating second layer or—in the case of an MWT-PERC cell—are segments of an insulating layer introduced directly on the semiconductor substrate.

When an MWT-PERC cell is used, alternatively, the back-side passivating dielectric can function as first insulating layer in the passage opening. The second insulating layer is then introduced in a separate layer, and in fact, onto the back-contact layer such as the Al layer introduced on the passivating dielectric.

The invention preferably provides that a strip-shaped electrically conducting second contact, which is connected in an electrically conducting manner with the back side, runs along at least one side of the strip-shaped segments of the electrically insulating second layer.

In order to simplify production technology without reducing the number of passage openings of standard back-side contact solar cells, it is optionally provided that the passage openings are disposed exclusively in two rows running parallel or substantially parallel to one another.

If a solar cell usually has 16 passage openings, which are arranged in four rows, then it is provided according to the invention that the passage openings are arranged in two rows of eight passage openings each. With this arrangement, finger-like contacts likewise proceed, e.g., radiate out from the passage openings and intersect the equipotential lines approximately perpendicularly.

Other details, advantages and features of the invention result not only from the claims, and from the features to be derived from the claims—taken alone and/or in combination—but also from the following description of preferred examples of embodiment to be taken from the drawing.

Herein is shown:

FIG. 1 a front view of a back-side contact solar cell;

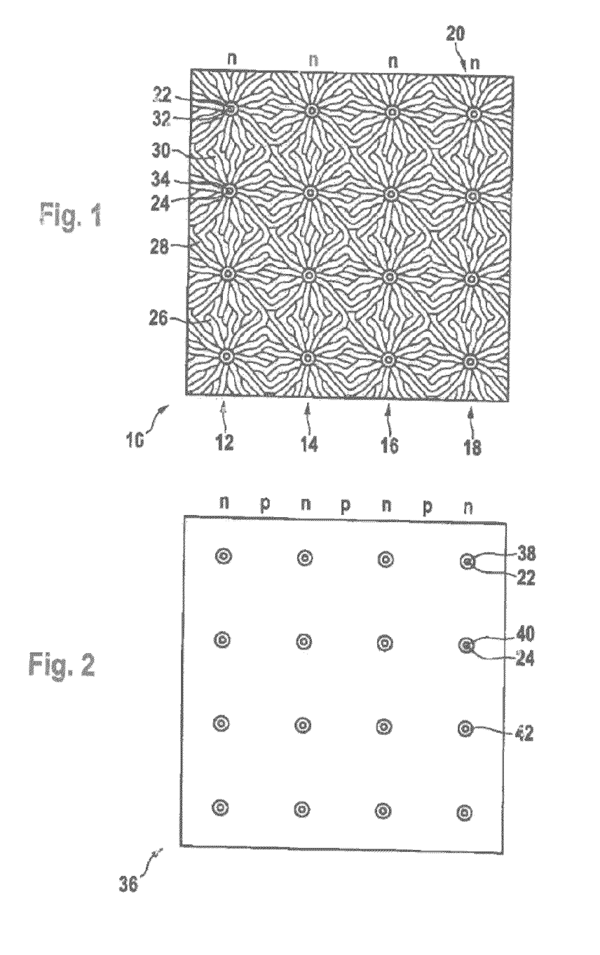

FIGS. 2-5 illustrations of the back side of the back-side contact solar cell of FIG. 1 according to different process steps;

FIG. 6 the front view of FIG. 1 after through-contacting has been produced;

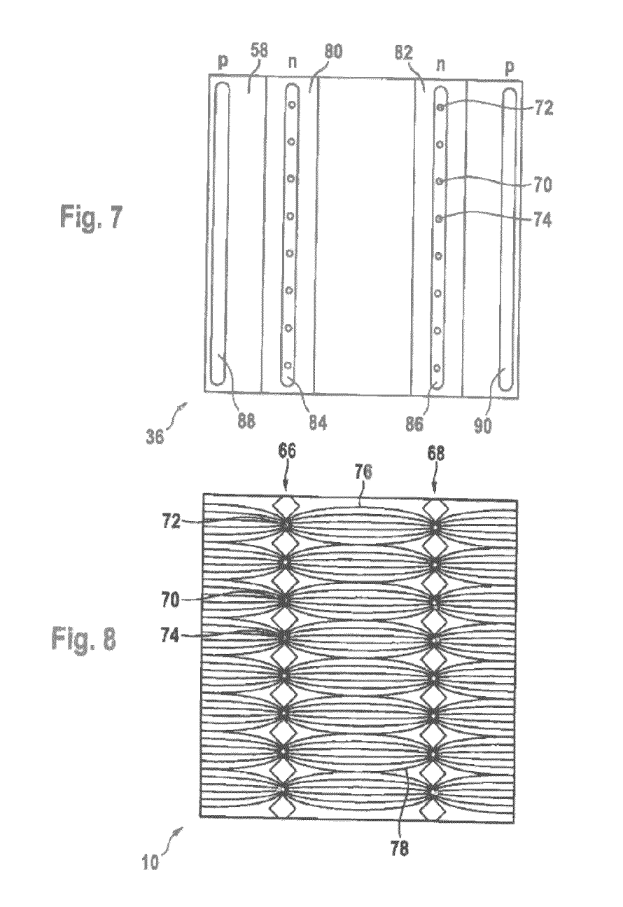

FIG. 7 an alternative embodiment of a back side of a back-side contact solar cell;

FIG. 8 the front side of the back-side contact solar cell according to FIG. 7;

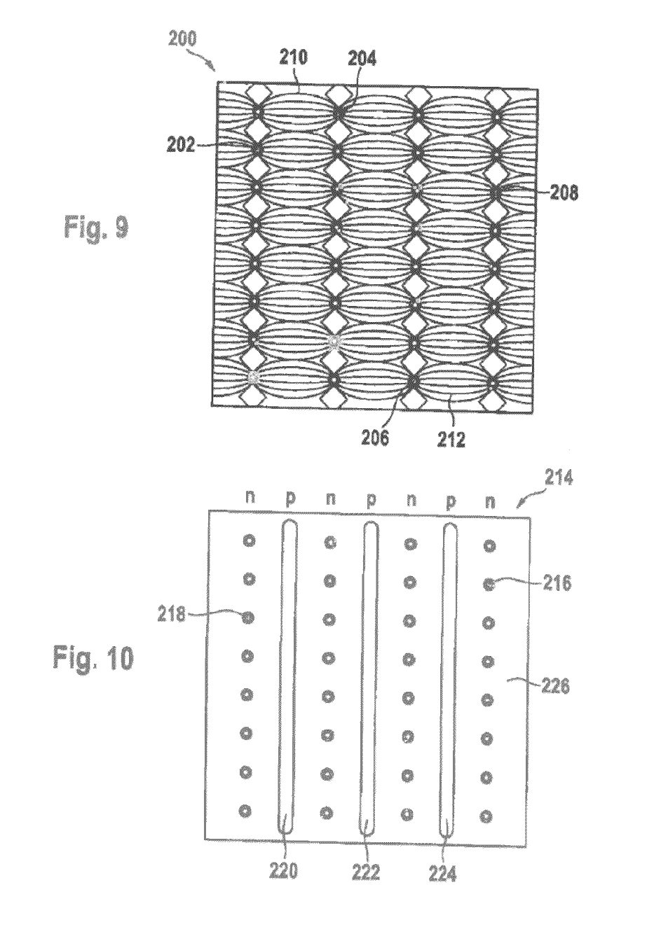

FIG. 9 an alternative embodiment to the back-side contact solar cell according to FIG. 7;

FIG. 10 back side of the back-side contact solar cell according to FIG. 9;

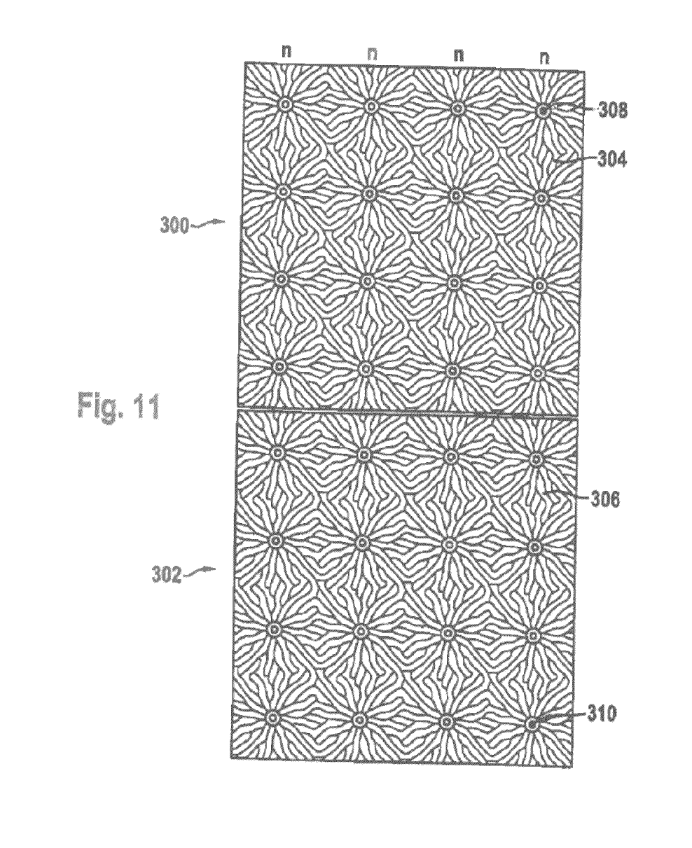

FIG. 11 front view of two solar cells to be connected;

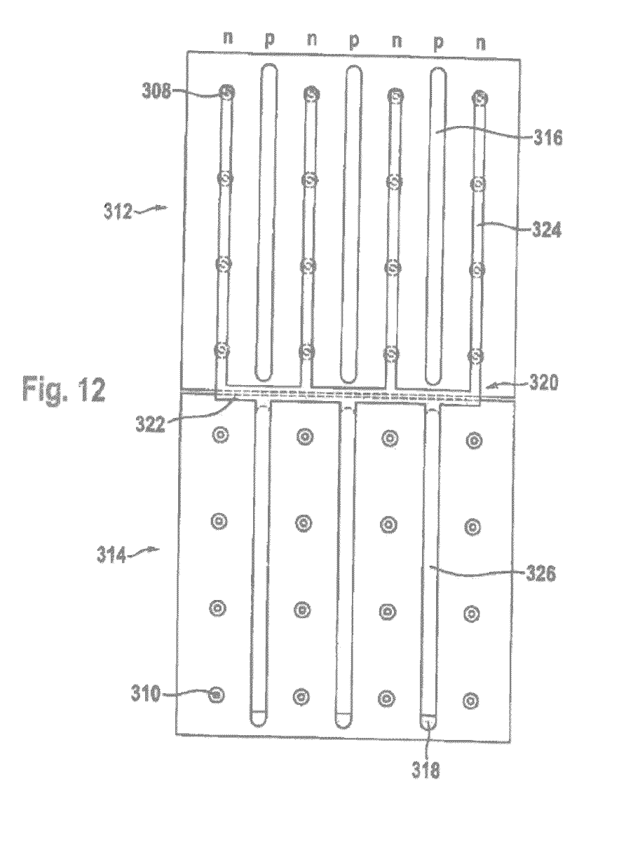

FIG. 12 the connected solar cells according to FIG. 11 in a back-side view;

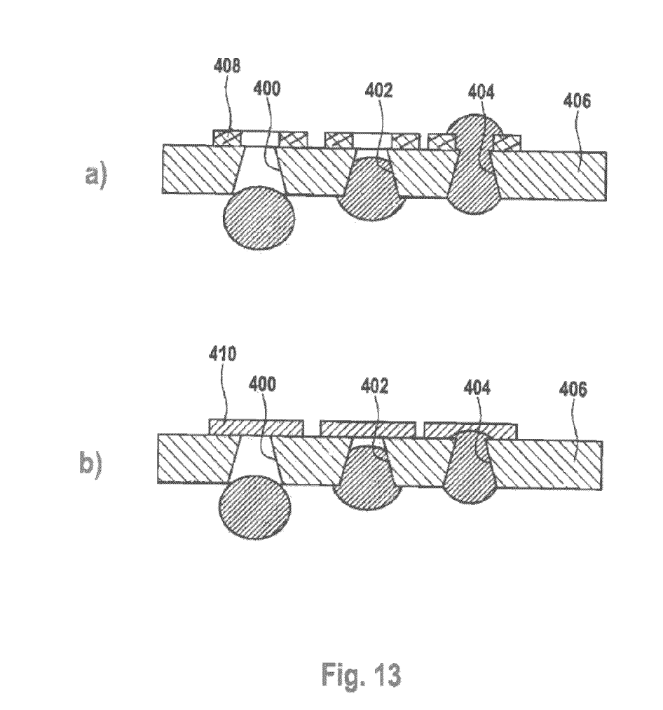

FIG. 13a, b schematic diagrams of the application of soldering material; and

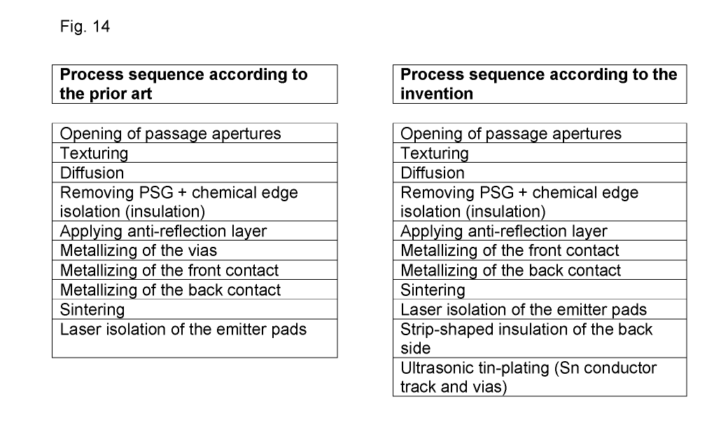

FIG. 14 method flow charts.

The design according to the invention of a back-side contact solar cell will be explained in the example of embodiment on the basis of a p-silicon-based crystalline semiconductor substrate, so that consequently, the emitter or n-contacts proceed from the front side, and the base or p-contacts proceed from the back side. The teaching according to the invention correspondingly applies also, however, to other semiconductor substrates or base dopings.

In FIG. 1, the front side 10, which faces the solar radiation, of a back-side contact solar cell according to the invention is shown in the form of a metal wrap-through (MWT cell). A wafer made of p-doped silicon, in which passage openings to be designated apertures are introduced in rows 12, 14, 16, 18, 20, forms the base of the MWT cell, several of these passage openings being characterized, for example, by the reference numbers 22, 24. An emitter layer (n-layer) is produced on the front side in a phosphorus diffusion step. The walls of the passage openings may also be covered with an n-layer. A metallizing forming a front contact 26 is subsequently introduced, e.g., by a printing process or masking technique, this metallizing running by radiating out in the known way from thin fingers 28, 30 leading to the passage openings 22, 24 also to be designated as apertures or vias. Since the passage openings 22, 24 form current sinks during operation of the solar cell, the fingers 28, 30 should run perpendicular or approximately perpendicular to the equipotential lines that run around the current sinks or surround the passage openings 22, 24, which surround the passage openings 22, 24.

According to the invention, in addition to the fingers 28, 30, a front-side contact region 32, 34 surrounding the apertures 22, 24 is formed therewith, and the contact fingers consequently pass over into this region. The front-side contact regions 32, 34 preferably have an annular structure or geometry and are composed of the same material as the metallizing, i.e., the front-side contact 26, and, in particular, are composed of silver or contain silver. The contact structures can have, in particular, a distance of up to 1 mm from the edge of the passage openings. Of course, the invention would not be abandoned if the annular front-side contact regions 32, 34 are composed of a material other than that of the contact fingers 28, 30. The contact regions can also completely cover the passage openings 22, 24, as FIG. 13b) illustrates. In another embodiment, the front-side contact regions extend directly up to the passage opening.

If the apertures 22, 24 do not have an n-layer on the inside, an insulating layer composed of an inorganic material in particular is introduced on the inner surfaces of the apertures 22, 24, this layer being designated the electrically insulating first layer and extending to the back side 36 of the solar cell. Corresponding to the embodiment example of FIG. 2, the insulating layer surrounds the apertures 22, 24 on the back side, as is indicated by the rings 38, 40, 42, which surround the apertures 22, 24 on the back side 36 of the solar cell.

The insulating layer can be introduced by screen printing or masking and spraying or by a microdispensing technique (dispenser, nozzles). A layer precipitated from the gas phase may also be used, in particular, as is common, e.g., for PERC cells.

In order to assure that the insulating layer extending into the apertures 22, 24 does not close the apertures 22, 24, the following measures are preferred. The insulating layer material is thinly applied, i.e., a liquid material is used, which is drawn into the rough wall structure of the substrate surrounding the apertures 22, 24, particularly due to capillary action. Subsequently the apertures 22, 24 can be “post-drilled”, e.g., by means of laser, i.e., opened.

A sparging of the apertures 22, 24 can be produced after spraying in a solution containing the layer material and after the solution has wetted the substrate material, such as silicon the walls of the apertures 22, 24.

A “post-processing” of the apertures 22, 24, however, is not necessary, if the liquid insulating material introduced into the apertures 22, 24 contracts during drying, so that the apertures 22, 24 are continuous for the through-contactings or vias.

Another proposal provides that the apertures 22, 24 are filled with a phosphorus glass solution and then this is dried. A diffusion process follows, in which phosphorus diffuses into the wall of the apertures 22, 24 and the back-side surroundings of the apertures 22, 24, i.e., an emitter is formed. Subsequently, the simultaneously forming phosphosilicate glass layer in the apertures 22, 24 is etched away, e.g., by means of hydrofluoric acid.

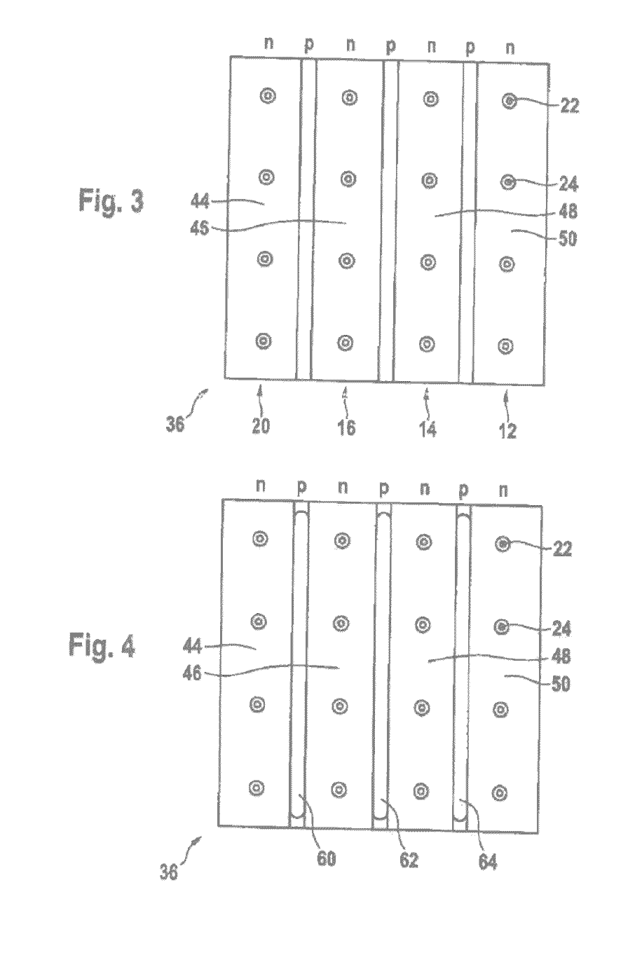

Alternatively or additionally, the possibility exists, corresponding to FIG. 3, of applying insulating layer strips 44, 46, 48, 50 on the back side 36 in strip form along the apertures 22, 24 running in the rows 12, 14, 16, 20, these strips extending into the apertures 22, 24 up to the preferably annular front-side contact regions 32, 34. The strip-shaped insulating layers 44, 46, 48, 50 are designated as the second insulating layer, segments of which consequently form the first insulating layer extending through the apertures 22, 24.

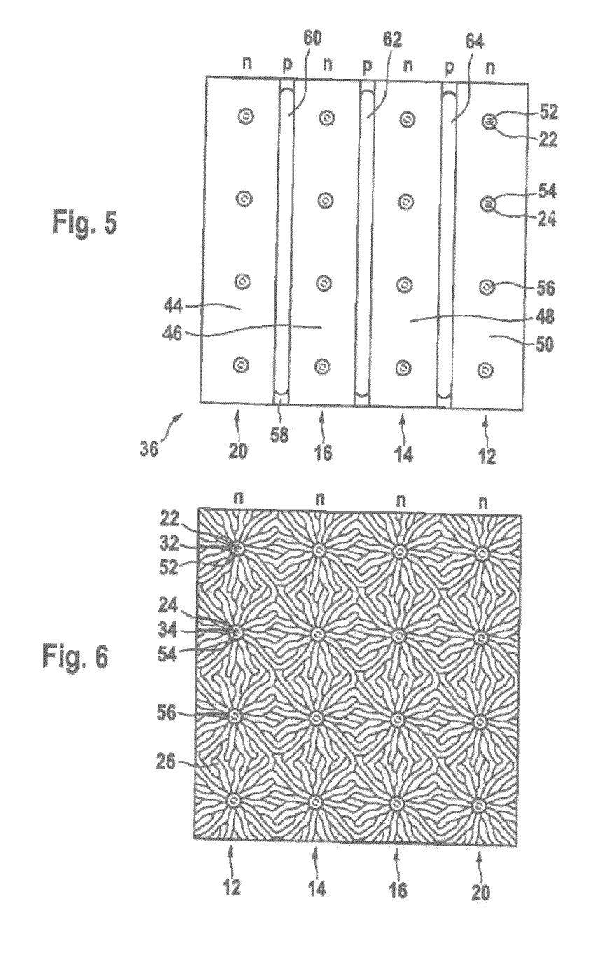

The first and second insulating layers are preferably produced in one operating step. In a second method step, a through-contacting of soldering material such as tin or tin/zinc or tin/aluminum alloys is conducted, supported by ultrasound, in such a way that an electrically conducting connection is formed, which extends from contacts in the region of apertures 22, 24 on the back side 36 of the solar cell to the soldering points 52, 54, 56 of the front-side contact regions 32, 34, as is shown by a comparison of FIGS. 5 and 6. The soldering points 52, 54, 56 are characterized by the same reference numbers on the front side. Thus, an electrically conducting connection between the front-side metallizing, which is called a front-side contact, is secured to the back side 36 of the solar cell. Subsequently, the back-side soldering points 52, 54, 56 can be connected in the usual way in an electrically conducting manner, in order to connect the solar cells.

The back side 36 is free between the strip-shaped insulating layer strips 44, 46, 48, 50 running along the apertures 22, 24 or vias disposed in the rows 12, 14, 16, 20, so that bars that are called busbars 60, 62, 64 can be applied, for example, by screen printing in the intermediate space on the back-side contact, which particularly is composed of aluminum or contains aluminum and covers the wafer, e.g., as a flat surface. So far, known techniques are applied.

Alternatively, recesses can be provided in the usual way in the aluminum layer 58, and soldering pads are found in these recesses, these pads then being cohesively connected to a connector, in order to enable a connection of the solar cells. Busbars 60, 62, 64 are also connected to the corresponding connectors.

The busbars 60, 62, 64 are most preferably soldering tracks that are produced by ultrasonic soldering. There also exists the possibility, however, of producing metal tracks from silver and/or copper and/or zinc by screen printing, plasma spraying, pad printing, or by means of electroplating. Materials such as Sn, Sn—Pb, Sn—Zn, Sn—Ag or Sn—Ag—Cu are also considered.

If the back contact has soldering pads, then these pads should be composed of silver and/or copper and/or zinc or one of the above-named materials, and may also be introduced by screen printing, plasma spraying or pad printing, or optionally by electroplating.

Instead of soldering points 52, 54, 56 at a distance from one another, it is more preferably provided that a strip of electrically conducting material is applied by means of ultrasound, or is supported ultrasonically, on the strip-shaped insulating layer segments 44, 46, 48, 50 along each row 12, 14, 16, 20, whereby the electrically conducting material passes through the apertures 22, 24 to the front-side contact regions 32, 34 corresponding to the teaching of the invention. This will be illustrated on the basis of FIGS. 7 and 8. In this case the back-side contact solar cells to be receiving these are distinguished from those of FIGS. 1-6 by the arrangement of the apertures, to the effect that they are disposed exclusively in two rows 66, 68, whereby, however, the total number of apertures corresponds to that of the embodiment examples of FIGS. 1-6, i.e., the number of current sinks is not changed. Corresponding to the previous explanations, the front side 10 has a metallizing that is formed by fingers 76, 78.

Corresponding to the teaching according to the invention, apertures 70, 72, 74 are surrounded on the front side by preferably annular front-side contact regions (which are not characterized in more detail), from which proceed the contact fingers 76, 78. The apertures 70, 72, 74 are lined by an insulating layer, which transitions into strip-shaped insulating layer segments 80, 82 that run along the back side 36 of the solar cell corresponding to the explanations of FIGS. 3 and 4. Instead of the annular contact regions, such regions may also be provided that completely cover the apertures 70, 72, 74, on the front side, or that extend up to the edge of the apertures.

Deviating from the examples of embodiment of FIGS. 1-6, a soldering material is not introduced separately into each aperture 70, 72, 74 in order to produce the electrically conducting connection between the front-side metallizing and the back side; rather the electrically conducting material in strip form is introduced by means of ultrasound, or is ultrasonically supported, along the strip-shaped insulating layer segments 80, 82, in order to form busbars 84, 86 that extend through the apertures 70, 72, 74 to the front-side contact regions.

There is consequently the possibility of forming busbars 84, 86 in the form of solder tracks, e.g., by ultrasonic welding. Metal tracks that can be composed of silver, copper or zinc can also be formed as busbars 84, 86, however, by means of screen printing, plasma spraying, pad printing, or electroplating.

The ultrasound soldering for the formation of the strip-shaped solder tracks 84, 86 is particularly provided according to a teaching that can be taken from DE-B-10 2010 016 814, and reference is made expressly to the disclosure thereof.

Thus, a solder wire can be introduced between a tool such as a sonotrode that applies ultrasonic vibrations and a gap running to a heating means; therefore, the solder wire melts and the molten solder then flows through the gap onto the back side of the solar cell.

As long as the through-contactings or vias are not connected on the back side via busbars, but are formed as punctiform n-contacts on the back side, soldering points (metal pads), e.g., made of silver, copper or zinc can be produced by screen printing, plasma spraying, pad printing, or by means of electroplating.

Materials such as Sn, Sn—Pb, Sn—Zn, Sn—Ag, Sn—Ag—Cu, or other suitable soldering materials are also considered as materials for the n-contacts formed as busbars or soldering points.

In the edge region of the solar cell and parallel to the busbars 84, 86, which connect the vias, i.e., the soldering material passing through the apertures 70, 72, 74, run busbars 88, 90, which can be designated as strip-shaped second contacts and are connected electrically with the back-side contact 58 of the solar cell.

In the case of a p-silicon-based substrate with front-side emitter on the side of incident light, the busbars 84, 86 consequently form the n-contacts and the busbars 88, 90 form the p-contacts.

In addition, it results from FIG. 8 that the contact fingers 76, 78 running to the current sinks, thus to the vias through the apertures 70, 72, 74 are disposed in such a way that they intersect perpendicularly or approximately perpendicularly the equipotential lines surrounding the vias. This shall be illustrated in principle in the drawing.

An embodiment of a back-side contact solar cell that is an alternative to the one of FIGS. 7 and 8 can be derived from FIGS. 9 and 10.

Deviating from the arrangement of the passage openings 70, 72, 74 of FIG. 8, the back-side contact solar cell 200 has passage openings 202, 204, 206 and 208, and thus vias, which are arranged in four rows, in order to connect fingers 210, 212 running on the front side and serving as current collectors in an electrically conducting manner to contacts running along the back side 214 of the solar cell 200. In this way, the contact fingers 210, 212 run in particular perpendicular or nearly perpendicular to the equipotential lines surrounding the vias, corresponding to FIG. 8.

The contact regions of the vias running on the back side, two of which are characterized, for example, by the reference numbers 216 and 218, which pass through the passage openings 202 and 208, can be connected together, corresponding to the example of embodiment of FIG. 7, via an electrically conducting, strip-shaped, running contact composed of tin, for example, and forming a busbar, as this is illustrated in FIG. 7. Between the contacts 216, 218 arranged in rows or the busbars connecting them, which are isolated in the way described previously with respect to the back side 214 of the solar cell 200, run busbars 220, 222, 224, which form the back-side contacts of the solar cell 200, and consequently, for a p-based semiconductor substrate, the p-contacts.

It is to be noted relative to the p-contacts designated as busbars 220, 222, 224 that they can be produced by application of bars in the screen-printing method, by plasma spraying, pad printing, or by electroplating. Alternatively, pads can be provided, which are then connected by means of a strip-shaped connector. Finally, there is also the possibility of providing the back side with the aluminum layer 214 over the entire surface, onto which strip-shaped solder tracks are applied, ultrasonically supported.

The back-side contact solar cells can be connected corresponding to the schematic diagrams taken from FIGS. 11 and 12. This is realized by means of comb-like contact structures, which mesh with one another.

For the connection of the back-side contact solar cells 300, 302 shown in FIG. 11, the front-side metallizings 304, 306 are guided through vias 308, 310 in the way described previously to the back sides 312, 314 of the solar cells 300, 302. The vias 308, 310 can then be connected together first by busbars, which run parallel to one another, as this has been explained, e.g., in connection with FIG. 7. Of course, a connection of the vias 308, 310 by means of busbars or similarly acting contact strips is not absolutely necessary.

The p-contacts, i.e., back-side contacts, are formed by busbars 316, 318, which run parallel to one another and parallel to the vias 308, 310, which are arranged in rows, as this is illustrated by FIG. 12.

For connecting the solar cells 300, 302, a comb-like contacting structure 320 is used, which comprises a cross-leg 322 running parallel to the edges of the solar cells 300, 302 adjacent to each other and lengthwise tines or legs 324, 326 projecting to both sides of this cross-leg.

In this case, the number of lengthwise legs 324 extending along the back side of the solar cell 300 is equal to the number of vias 308 of the cell 300 arranged in rows, and the number of lengthwise legs 326 assigned to the solar cell 302 is equal to that of the busbars 318 of the cell 302. The contact structure 320 is now positioned in such a way that the lengthwise legs 324 are connected to the vias 308 of the cell 300 in an electrically conducting manner, and the lengthwise legs 326 are connected to the busbars 318 of the solar cell 302 in an electrically conducting manner. The cross-leg 320 is then electrically isolated from the solar cell 300, at least with respect to the back side 312 of the solar cell 300, in order to avoid a short circuit.

Additional adjacent solar cells are then connected to one another corresponding to the contacting structure 320, which is shown.

Once more, the method for the through-contacting of the passage openings can be taken in principle from FIGS. 13a), 13b), as this has been explained previously. The passage openings for through-contacting are characterized by the reference numbers 400, 402, 404, and pass through the solar cell substrate 406 from the front side to the back side. In this case, the passage openings 400, 402, 404 on the front side are adjacent to the previously explained contact regions 408, 410, whereby, corresponding to the illustration according to FIG. 13a), the contact regions 408 characterized by a cross-hatching are adjacent to the openings, which run annularly on the front side, of the passage openings 400, 402, 404, whereas, according to the example of embodiment of FIG. 13b), the contact regions 410 close the passage openings 400, 402, 404 on the front side.

As is illustrated in FIG. 13a), the annular contact regions 408 preferably terminate at a distance from the upper edge of the passage openings 400, 402, 404, in order to ensure that shunts do not occur during sintering. In particular, the distance between the inner edge of the annular contact regions 408 and the edge of the passage openings 400, 402, 404 amounts to between 50 μm and 1000 μm, and at the same time, one does not depart from the invention even when the annular contact region 408 proceeds directly from the edge of the passage openings 400, 402, 404.

In order to bring the soldering material into the passage openings 400, 402, 404, a tool such as a sonotrode, which is stimulated by ultrasonic vibrations, acts on the soldering material, as this has been described in DE-B-10 2010 016 814. The frequency of the ultrasonic vibrations can lie in the range between 20 kHz and 100 kHz. The soldering material, which is indicated in principle by a circle having shading, penetrates into the passage openings 400, 402, 404 to an extent that the contact regions 408, 410 running on the front side are contacted and a cohesive connection is entered into. The soldering material penetrates into the passage openings 400, 402, 404, in particular, when a soldering track is applied onto the second layers composed of electrically insulating material in strip shape as previously described, whereby soldering material penetrates into the passage openings 400, 402, 404 simultaneously when sweeping through the passage openings. In this case, corresponding to the teaching of DE-B-10 2010 016 814, the solar cell or the substrate 406 is guided under the sonotrode, along which the soldering material flows to the substrate 406, i.e., the back side thereof. The soldering material is soldered onto the back side of the substrate 406, in the passage openings 400, 402, 404, and the contact regions 408, 410. The soldering material soldered onto the back side is not shown in FIGS. 13a), b).

The sequential steps of the process that are carried out for the production of a solar cell according to the prior art and according to the invention will be described once more purely in principle one the basis of FIG. 14. In this case, the essential method steps will be explained purely in principle.

The process sequence according to the prior art can be taken from the flow chart on the left in FIG. 14. Thus, in the known way, passage apertures (vias) are produced first in a substrate, for example, composed of a p-conducting silicon, and then texturing is provided to the front side of the substrate. A diffusion step is subsequently performed, in particular with the use of a phosphorus-containing doping source. The formed phosphosilicate glass is subsequently removed and a chemical edge isolation is carried out. As the next step, an anti-reflection layer is formed by introducing a silicon nitride later, for example. In a following step, the passage openings are metallized. After a drying step, the front side is then metallized in order to thus apply, e.g., by screen printing, fingers and front-side contact regions that surround the vias. After a repeated drying, in the next method step, the back-side metallizing is formed by a flat-surface application, in particular, of an electrically conducting layer such as an aluminum layer. Subsequently, after another drying step, there is a sintering step. Then the emitter pads surrounding the vias on the back side are isolated from the back-side metallizing, in particular, by means of a laser.

A solar cell produced according to the invention undergoes the same method steps in process technology as has just been explained, up through the formation of the anti-reflection layer. Deviating from the prior art, it is not the metallizing of the vias that is then performed, but rather the metallizing of the front contact, i.e., in particular, a contacting structure in the form of fingers applied by screen printing and the front contact regions, which surround the passage openings or vias, which can surround the passage openings, in particular, annularly, corresponding to the teaching of the invention. After the drying, a metal layer such as an aluminum layer is subsequently applied onto the back side, in particular over the entire surface, and dried. Of course, the back-side contact layer applied over the entire surface has recesses in the region of the vias, since otherwise shunts would occur. The sintering step is then performed. Subsequently, the back-side contact region surrounding the vias on the back side is isolated from the back-side metallizing, an electrical separation being especially carried out by lasers. Then, along the openings, i.e., particularly in strip shape, the isolation designated previously as the electrically insulating second layer is applied, which then extends through the passage openings when the passage openings do not have an emitter layer, in order to assure the necessary electrical isolation opposite the substrate. Then soldering material is applied, supported by ultrasound, along the strip-shaped electrically insulating second layer, and in fact, ultrasonically supported, whereby, simultaneously, the soldering material, supported ultrasonically, passes through the passage openings to the front contact.

1-14. (canceled)

15. A method for the production of a solar cell having a semiconductor substrate of a first conductivity type, which has a front side and a back side, comprising the method steps of:
producing a plurality of passage openings extending from the front side to the back side;
creating a layer of a second conductivity type that is opposite to the first conductivity type along the front side;
producing a front-side contact in the form of a metallizing with front-side contact regions that are electrically conducting delimiting the plurality of passage openings on the front side, and producing a back-side contact, the back-side contact having back-side contact regions that are electrically isolated or insulated with respect to the back side adjacent to the plurality of passage openings on the back side, the plurality of passage openings have on an inside either an electrically insulating first layer or a layer of the conductivity type opposite to the first conductivity type, wherein the front-side contact is connected in an electrically conducting manner by introducing an electrically conducting material into the plurality of passage openings;
connecting the back-side contact regions to one another; and
introducing a soldering material, supported by ultrasound, as the electrically conducting material, proceeding from the back side through the plurality of passage openings to the front-side contact regions, with simultaneous formation of the back-side contact regions.

16. The method according to claim 15, wherein the front-side contact regions adjacent to the plurality of passage openings are formed as annularly surrounding or covering the plurality of passage openings.

17. The method according to claim 15, wherein the front-side contact regions adjacent to the plurality of passage openings surround the plurality of passage openings so that an edge of the passage opening is a distance from the front-side contact regions.

18. The method according to claim 17, wherein the distance is between 50 μm and 1000 μm.

19. The method according to claim 15, wherein at least a portion of the plurality of passage openings are arranged in at least one row running along a line, further comprising an electrically insulating second layer that is applied onto a back-side contact layer forming the back-side contact on the back side, wherein the electrically insulating second layer extends into the plurality of passage openings for the formation of the electrically insulating first layer.

20. The method according to claim 19, wherein the electrical conducting material is applied, supported by ultrasound, in strip shape on the electrically insulating second layer, for the formation of first strip-shaped contacts, whereby simultaneously, the electrically conducting material penetrates into the plurality of passage openings to the front-side contact regions.

21. The method according to claim 20, wherein at least a portion of the plurality of passage openings are arranged in at least two rows, wherein the electrically insulating second layer has a strip-shaped segment that runs along each row, and a second strip-shaped contact connected to the back-side contact is formed parallel to the strip-shaped segment that runs along each row.

22. The method according to claim 21, wherein the solar cell is a first solar cell, further comprising a second solar cell, wherein the first solar cell and the second solar cell each have the first and second strip-shaped contacts, and wherein the first strip-shaped contact of the first solar cell and the second strip-shaped contact of the second solar cell are connected in an electrically conducting manner to one another in opposite-lying edge regions of the first and second solar cells by a contacting structure on which the first and second solar cells are positioned.

23. The method according to claim 21, further comprising a sonotrode that can apply ultrasonic vibrations that is guided along each row of passage openings, and ultrasonic vibrations are transferred by the sonotrode onto the respective electrically conducting material applied in strip shape.

24. The method according to claim 23, wherein the ultrasonic vibrations produce at least two first strip-shaped contacts simultaneously.

25. The method according to claim 19, wherein the back-side contact layer is an Al layer.

26. The method according to claim 21, wherein the at least two rows run parallel to one another.

27. The method according to claim 15, wherein the semiconductor substrate is a p-silicon-based crystalline semiconductor substrate.

28. The method according to claim 15, wherein at least a portion of the plurality of passage openings are arranged in at least one row running along a straight line.

29. A back-side contact solar cell comprising:
a semiconductor substrate of a first conductivity type, which has a front side and a back side, with a front-side layer of a conductivity type opposite to the first conductivity type,
a plurality of passage openings, extending from the front side to the back side,
front side contacts formed by a front-side metallizing and a back-side contact that is formed,
wherein the front-side contact is connected in an electrically conducting manner, through the plurality of passage openings, to back-side contact regions surrounding the plurality of passage openings on the back side, and the back-side contact regions are connected to one another in an electrically conducting manner and are electrically isolated opposite the back side, wherein at least a portion of the plurality of passage openings are arranged in a row, the plurality of passage openings are delimited on the front side by an electrically conducting contact region forming front side contact regions, and the plurality of passage openings have on an inside either an electrically insulating first layer or a layer of the conductivity type opposite to the first conductivity type,
an electrically insulating second layer running along the back side extends in strip form along the plurality of passage openings arranged in the row, and in that soldering material as an electrically conducting material applied with ultrasound support extends along the electrically insulating second layer through the plurality of passage openings to the front-side contact regions, whereby the electrically conducting material extending along the electrically insulating second layer forms an electrically conducting first contact.

30. The back-side contact solar cell according to claim 29, wherein the electrically insulating first layer covering each of the plurality of passage openings on the inside are segments of the electrically insulating second layer or a dielectric layer applied directly on the back side of the semiconductor substrate.

31. The back-side contact solar cell according to claim 29, further comprising a strip-shaped electrically conducting second contact connected in an electrically conducting manner to the back side runs along at least one side of the electrically insulating second layer that extends in a strip form.

32. The back-side contact solar cell according to claim 29, wherein said electrically conducting first contact is a plurality of strip-shaped electrically conducting first contacts running substantially parallel to one another and a plurality of strip-shaped electrically conducting second contacts run along the back side, whereby the strip-shaped electrically conducting first contacts are connected in an electrically conducting manner by a contacting structure in a first edge region of the solar cell running crosswise to the strip-shaped electrically conducting first contacts, and the strip-shaped electrically conducting second contacts are connected in an electrically conducting manner in an opposite-lying edge region of the solar cell.

33. The back-side contact solar cell according to claim 32, wherein the contacting structure has a comb-like geometry with cross-leg and lengthwise legs running on both sides of the cross-leg, in that the lengthwise legs on one side are connected to the strip-shaped electrically conducting first contacts of the solar cell and the lengthwise legs on the other side are connected to the strip-shaped electrically conducting second contacts of a second solar cell corresponding to the solar cell.

34. The back-side contact solar cell according to claim 29, wherein the plurality of passage openings are disposed in two rows running substantially parallel to one another.

35. The back-side contact solar cell according to claim 29, wherein the semiconductor substrate of the first conductivity type is a p-silicon-based crystalline semiconductor substrate.
